(19) United States
(12) Patent Application Publication
(10) Pub. No.: US 2017/0131363 A1
(43) Pub. Date: May 11, 2017

(54) Improved Battery Testing Device

(71) Applicant: Custom and Contract Power Solutions (CCPS) Limited, Rosyth (GB)

(72) Inventors: Nigel Scott, Elie, Leven (GB); Dennis Jones, Clovenfords, Galashiels (GB)

(73) Assignee: Custom and Contract Power Solutions (CCPS) Limited, Rosyth (GB)

(21) Appl. No.: 15/319,590

(22) PCT Filed: Jun. 17, 2015
(86) PCT No.: PCT/EP2015/063645

§ 371 Date: Dec. 16, 2016

(30) Foreign Application Priority Data
Jun. 18, 2014 (GB) 1410865.8

(51) Int. Cl. G01R 31/36

(52) U.S. Cl. CPC G01R 31/3679; G01R 31/3662

(57) ABSTRACT

A method of determining a level of deterioration in a battery, the method comprising: deriving a value of capacitance for the battery; and using the derived value of capacitance, deriving the level of deterioration of the battery.

The present invention relates to batteries and testing or measuring devices for batteries. In particularly, but not exclusively, the invention relates to determining deterioration in batteries; improved methods and apparatus for determining the resistance of batteries; and methods and apparatus for measuring very low current.

### Determining Deterioration in Batteries

At present, the most effective method of determining the condition of sealed standby lead acid batteries in situ, without disconnection from the critical load, is to measure the internal impedance, conductance or resistance of each cell. The resistance value derived has been shown to have a relationship with the condition of the cell under test and is known to more than double in value over the life of the cell, or when failure modes arise. Resistance is, however, a less reactive component of the cell's electrochemistry than is desirable for the prediction of cell deterioration, since it changes little in the early stages of failure modes or end of life, with deviation perhaps only being reliably detected when the cell has deteriorated to 60-50% of its original (rated) capacity, and is only indirectly related to the State of Health (SoH) or State of Charge (SoC) of the cell. The direct SoH or SoC of the cell cannot be inferred from the impedance, which can only give a general indication of a gross deterioration. In addition, studies have shown that separate cells in the same battery can, for very similar impedance values, have widely varying energy capacities. This means that only relatively high values of resistance above par can reliably indicate real deterioration.

Since the standby battery industry consider that the battery is suspect and should be changed out when cell deterioration has reached a loss of 20% capacity (i.e. when 80% capacity remains) it is extremely desirable that the early stages of deterioration be reliably detected and not just the very late stages.

### Improved Methods and Apparatus for Determining the Resistance of Batteries

As previously stated, the most effective method of determining the condition of sealed standby batteries in situ, without disconnection from the critical load, is to measure the internal resistance of each cell. Although of lesser importance than resistance, it is also desirable that a record of the cell terminal voltages is made as there may be indication of catastrophic failure, therefore the terminal voltages are measured at the same time and immediately prior to the resistance test.

In almost all test systems however, the testing of resistance, impedance or conductance involves drawing a current from the cell under test. If too small, this test current can be affected by system noise, or may not penetrate the gassing or charge overvoltage layer of the cells, therefore a current of sufficient magnitude must be used to ensure reliable results.

To save time and resource it is desirable that hand-held battery test instruments record the terminal voltage immediately before performing a resistance test, i.e., during the same test cycle. However drawing a test current from each cell in turn, in a battery consisting of more than a few cells in series, can have the undesirable effect of altering the float voltage of the cells remaining to be tested, making the voltage measurements of the latter cells in the battery inaccurate.

This problem often necessitates measuring each cell in the battery with the hand-held instrument twice, one series to measure the terminal voltages of the individual cells and a second test series to record the individual cell resistances.

A further problem with hand-held instruments is that, since a reasonable amount of current must be employed in the test, and all instruments must dissipate the power consumed internally via resistors or active transistors operating in the linear mode, the instruments have the problem of disposing of the heat dissipated internally by the test.

As a result, instruments that draw sufficient current to perform a reliable resistance test may present a danger of burns to the operator, therefore the most reliable instruments are often large and unwieldy, often with fans to disperse the heat product. It is not uncommon for these instruments to impose a pause in the testing series to allow the instrument to cool down.

Also, in testing large battery systems, batteries for the operation of, and internal to, the test instrument can be exhausted before testing is complete, necessitating a pause in the testing process of several hours while the instrument is recharged.

### Methods and Apparatus for Measuring Very Low Current

There are many applications where the measurement of very small electrical currents is desirable but where traditional Hall-effect or fluxgate transducers are, for various reasons, not possible. Such a situation is that of standby battery systems.

It is widely recognised that many battery failure modes and end of life characteristics can be manifest as changes in the float current, however traditional transducer means of measuring this current suffer from several drawbacks.

Battery currents in permanent monitoring systems are measured by means of a current transducer, or sensor, which must encircle the primary load current carrying cable. Charging and subsequent float charging in these systems is almost universally carried out via the main load cables to and from the battery, which can be fairly substantial in diameter. To be commercial the transducer must be of a size to cater for several different diameters of primary cable; such a sensor tends to be bulky and expensive.

At the present time, only the discharge and subsequent recharge currents can be measured with the required accuracy, as the technology employed in the current transducers is almost universally Hall-effect, which is accurate enough for the measurement of low-medium and high currents, but has serious limitations in the measurement of very low (milliamp) currents. In continuous monitoring systems a major problem is temperature drift in the Hall-effect cells, which can materially affect very small measurements, and another is remanence or hysteresis.

Discharge and charge currents can be several times the rated A/h of the battery and may be from a few tens of amps to several hundreds or thousands of amps, in the reverse polarity to that of float or charge.

Remanence is a permanent offset effect which occurs during a high current charge or discharge, where the zero measurement point of a transducer is shifted in one direction or the other by a polarising effect of high currents on the magnetic transducer core. This results in a permanent unpredictable offset many times larger than the value of the current required to be measured.

Hand-held current clamps have different problems, in that they must utilise an opening or split-core device to effect a measurement. In this case the core is constructed in two hinged sections, which open in order to encircle the Primary Current Conductor. Constructing the magnetic core in two sections significantly reduces the permeability of the magnetic core common to all such sensors, and degrades the measurement accuracy to an unacceptable level in the very low milliamp range.

### NOMENCLATURE

Cell: Single electrochemical voltage/current generator and energy storage unit with a nominal terminal voltage of 2 volts.

Monobloc (or bloc) or Jar: one or more lead-acid electrochemical cells in the same enclosure.

Battery: the term ‘battery’ in the standby industry normally indicates not an individual cell, but the complete series or series/parallel arrangement of cells in order to achieve the required terminal voltage and/or power. An example of a typical ‘battery’ could be 460 volts 500 kilowatts.

VRLA, SLA, AGM, GEL: Sealed lead-acid cells where the electrolyte is of a particular composition to allow the recombination of gases, generated during discharge and charge, back into electrolyte when re-charge is complete.

Float (charging) current: a small DC maintenance charging current always present after the battery is fully charged, with the object of replacing any energy lost in the process of self-discharge. Its magnitude is dependent on the total voltage fixed by the charger, the natural requirement of the chemistry used in the cells that form the battery and the condition of the cell, but is generally in the range 0.5 to 1.5 mA per battery A-hr.

Float voltage: the DC voltage developed across a cell by the float current. It is normally 1-2 hundred millivolts above the natural open circuit voltage of the cell.

Charge overvoltage, also known as the gassing voltage or apparent energy layer: The difference between the open circuit voltage of a fully charged cell and the float voltage developed across the cell by the float current. The apparent energy layer provides virtually no energy during a discharge; the cell falling immediately from its float voltage to its open circuit voltage before it begins to support the critical load.

UPS (Uninterruptible Power Supply) system: (DC) A system, composed of a rectifier with a supporting battery and the critical load connected across the output, or (AC) a system composed of a rectifier with a battery and the input of an inverter connected across its output; the critical load being connected across the output of the inverter. In both systems it is normal for the rectifier to support the critical load and charge/maintain the battery simultaneously.

Critical Load: the load (application) which must be continuously maintained and protected by the battery or UPS/battery system against loss of supply.

Cell internal resistance: cell resistance (the cell's opposition to the passage of a direct current (DC), Impedance (the cell's reaction to alternating current (AC) perturbation, or unipolar pulsed load current) and Conductance (the reciprocal of resistance) are all methods of attempting to detect the deterioration of the cell.

Vdrop: Voltage drop over test; the maximum magnitude of voltage change (drop), caused by the application of a test load, between the voltage immediately prior to the test start and the instantaneous voltage immediately before the test current is terminated.

State of Health (SoH), State of Charge (SoC): Although these terms are used in isolation, the conditions they describe are inextricably linked: A cell may not be fully charged if any part of the cell has deteriorated to the point where the recharge cannot be fully accepted and does not allow the cell to subsequently discharge its specified optimum energy (SoH<100%). On the other hand, an otherwise healthy cell which is partially discharged (SoC<100%) has been subject to electrochemical changes which, although this condition may be rectified by recharging, at that instant is, by definition, in a state of deterioration. A battery may be said to have a 100%, state of health if, when fully charged, it can deliver, as a minimum, the designed Ampere/hour capacity.

PCC: Primary Current Conductor—the conductor in which the current is to be measured.

Unless otherwise indicated, the term ‘resistance’ is used generically to indicate ‘simple’ AC impedance, DC resistance or conductance (1/resistance; conductance behaves inversely to resistance).

According to a first aspect of the present invention there is provided a method of determining a level of deterioration in a battery, the method comprising:
deriving a value of capacitance for the battery; and
using the derived value of capacitance, deriving the level of deterioration of the battery.

The method may include connecting a load to the battery to apply a constant current to the battery. The method may include measuring the resulting total voltage drop. The method may include deriving a value of capacitance for the battery from the measured total voltage drop.

The method may include using a perturbation device to apply the constant current to the battery. The perturbation device may comprise a controlled transistor. The method may include controlling the current using processing means. The processing means may comprise a microprocessor or Digital Signal Processor.

The method may include determining a resistance value for the battery. The method may include determining a pseudo-vertical voltage drop to determine the resistance value. The method may include determining a first pseudo-vertical voltage drop at the start of the test and a second pseudo-vertical voltage drop at the end of the test. The method may include determining an average pseudo-vertical voltage drop from the first pseudo-vertical voltage drop and the second pseudo-vertical voltage drop. The method may include dividing the pseudo-vertical voltage drop by the applied constant current.

The method may include using the determined pseudo-vertical voltage drop and the determined resistance value together to determine whether the deterioration is at an early or a later stage.

The method may include deriving a value of the surface capacitance for the battery and, using the derived value of surface capacitance, deriving the level of deterioration of the battery.

The method may be carried out using a mobile or handheld device. The method may be carried out using a continuous monitoring system.

The battery may comprise a standby battery. The battery may comprise a plurality of cells. The method may include deriving a value of capacitance for the cell and, using the derived value of capacitance, deriving the level of deterioration of the cell.

The method may include comparing measured data from one cell with measured data from one or more other cells of the battery. The method may include deriving a Gaussian distribution from the data of all the measured cells. The method may include identifying excessive deterioration of a cell by identifying a standard deviation for a cell which is greater than a predetermined threshold value.

Alternatively or in addition, the method may include comparing measured data from one cell with historical measured data from the same cell of the battery. The method may include deriving a Gaussian distribution from the measured data and the historical measured data.

The method may include measuring the temperature of the cell. The level of deterioration of the battery may be derived using the derived value of capacitance and the temperature of the cell.

According to a second aspect of the present invention there is provided an apparatus for determining a level of deterioration in a battery, the apparatus comprising:
processing means adapted to:
   derive a value of capacitance for the battery; and
   using the derived value of capacitance, derive the level of deterioration of the battery.

The apparatus may include a load which is connectable to the battery to apply a constant current to the battery. The apparatus may include sensing means for measuring the resulting total voltage drop. The processing means may be adapted to derive a value of capacitance for the battery from the measured total voltage drop.

The apparatus may include a perturbation device to apply the constant current to the battery. The perturbation device may comprise a controlled transistor. The apparatus may include a microprocessor or Digital Signal Processor for controlling the current.

The processing means may be adapted to determine a resistance value for the battery. The processing means may be adapted to determine a pseudo-vertical voltage drop to determine the resistance value.

The processing means may be adapted to use the determined pseudo-vertical voltage drop and the determined resistance value together to determine whether the deterioration is at an early or a later stage.

The processing means may be adapted to derive a value of the surface capacitance for the battery and, using the derived value of surface capacitance, derive the level of deterioration of the battery.

The apparatus may comprise a mobile or handheld device. The apparatus may comprise a continuous monitoring system.

The battery may comprise a standby battery. The battery may comprise a plurality of cells. The processing means may be adapted to derive a value of capacitance for the cell and, using the derived value of capacitance, derive the level of deterioration of the cell.

The apparatus may include a temperature sensor for measuring the temperature of the cell. The processing means may be adapted to derive the level of deterioration of the battery using the derived value of capacitance and the temperature of the cell.

According to a third aspect of the present invention there is provided an apparatus for testing the resistance of a battery comprising:
connection means for connecting the apparatus to the battery;
an energy storage device;
energy conversion means adapted to transfer a first amount of current from the battery to the energy storage device; and
processing means adapted to determine the resistance of the battery using the current transferred from the battery,
wherein the energy conversion means is adapted to transfer a second amount of current to the battery from the energy storage device after the resistance has been determined.

The battery may comprise a standby battery. The battery may comprise a plurality of cells. The apparatus may be adapted to test the resistance of a cell.

The connection means may comprise Kelvin connections.

The energy storage device may be adapted to power the apparatus.

The first amount of current may be greater than the second amount of current by a third amount of current. The energy storage device may store the third amount of current.

The apparatus may be adapted to measure the resistance of a strap connecting two adjacent cells of the battery.

The connection means may be connectable to each terminal of the strap. The energy conversion means may be adapted to transfer the third amount of current to the strap. The processing means may be adapted to determine the resistance of the strap using the resulting voltage drop from the third amount of current applied to the strap.

According to a fourth aspect of the present invention there is provided a method of testing the resistance of a battery comprising:
transferring a first amount of current from the battery to an energy storage device; and
determining the resistance of the battery using the current transferred from the battery,
wherein the method includes transferring a second amount of current to the battery from the energy storage device after the resistance has been determined.

The battery may comprise a standby battery. The battery may comprise a plurality of cells. The method may include testing the resistance of a cell.

The method may include connecting the energy storage device to the cell using Kelvin connections.

The first amount of current may be greater than the second amount of current by a third amount of current. The energy storage device may store the third amount of current.

The method may include measuring the resistance of a strap connecting two adjacent cells of the battery.

The method may include transferring the third amount of current to the strap. The method may include determining the resistance of the strap using the resulting voltage drop from the third amount of current applied to the strap.

According to a fifth aspect of the present invention there is provided a method of measuring a current in a circuit, the method comprising the steps of:
generating a current in a Primary Current Conductor (PCC) of the circuit;
measuring the current flowing between two measuring points along the PCC;
measuring a first voltage drop between the two measuring points;
determining a resistance of the PCC by calculating a ratio of the measured voltage drop and the measured current;
cease generating the current in the PCC;
measuring a second voltage drop between the two measuring points; and
determining the current in the circuit by calculating a ratio of the measured second voltage drop and the determined resistance.

The generated current may be a single or multiple pulsed or oscillating current.

The generated current may be measured using a shunt resistor. The shunt resistor may be in series with a current generator.

The first voltage drop may be measured using a capacitor.

The method may include generating the current in the PCC in a first flow direction. The generated current may be a single pulse of DC current. The method may include generating a second single pulse of DC current in a second opposite flow direction.

The method may include determining the first voltage drop by measuring the voltage drop for each flow direction and determining an average of the measured values.

The method may include carrying out the method steps for a plurality of straps of a battery.

The method may include detecting any current imbalance between the positive and negative terminals of the battery caused by any earth leakage.

The method may include tracing any current imbalance to its causal location.

According to a sixth aspect of the present invention there is provided an apparatus for carrying out the method according to the fifth aspect of the invention.

Embodiments of the present invention will now be described, by way of example only, with reference to the accompanying drawings in which:

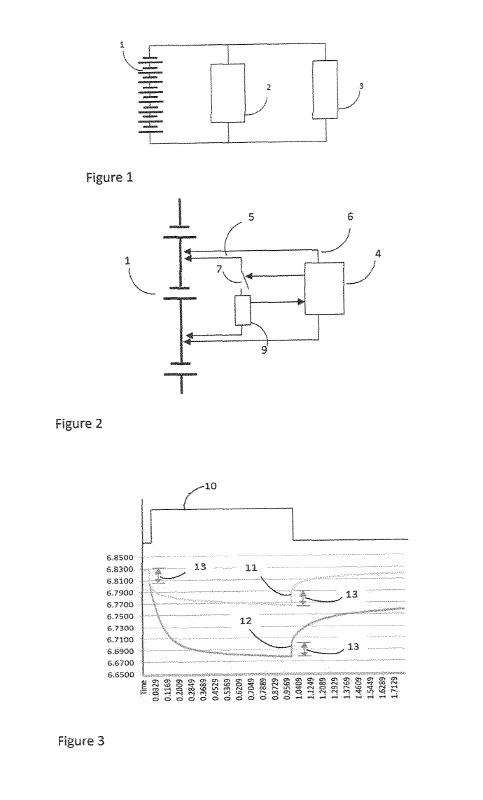

FIG. 1 is a schematic diagram of a battery connected to a charger and a load;

FIG. 2 is a schematic diagram of a test set up according to a first aspect of the invention for measuring cell resistance and capacitance;

FIG. 3 is a graph of the voltage reaction of a lead-acid battery to a switched current controlled stimulus (load);

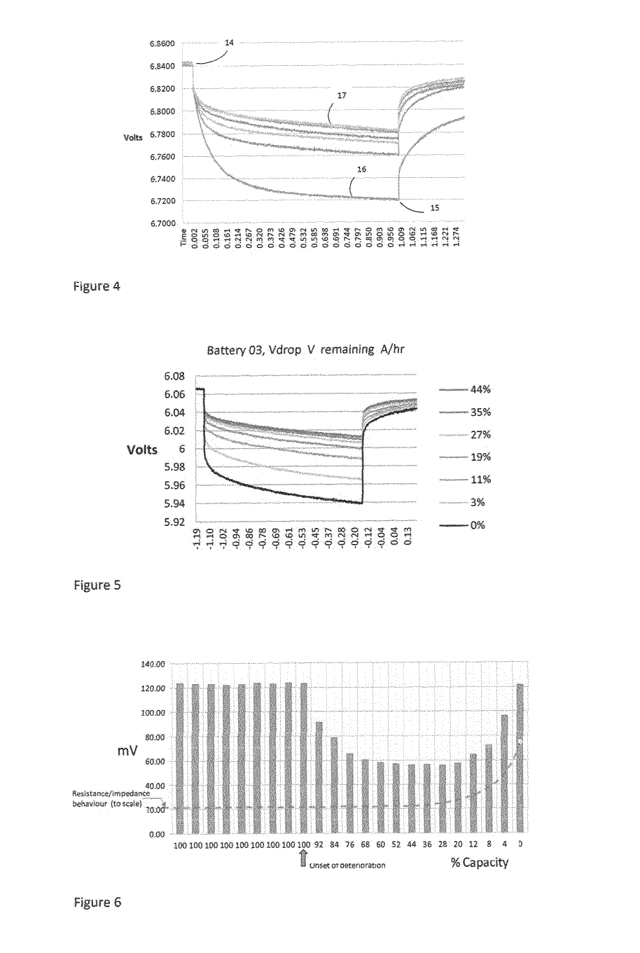

FIG. 4 is a graph of the voltage reaction of a lead-acid battery in the very early stages of deterioration, under current controlled stimulus;

FIG. 5 is a graph of a lead-acid battery in the latter stages of deterioration, under current controlled stimulus;

FIG. 6 is a graph of the progression of depth of test voltage response of a battery under current controlled stimulus as the battery deteriorates, and resistance, derived at constant current load and expressed in millivolts, is included as a comparison.

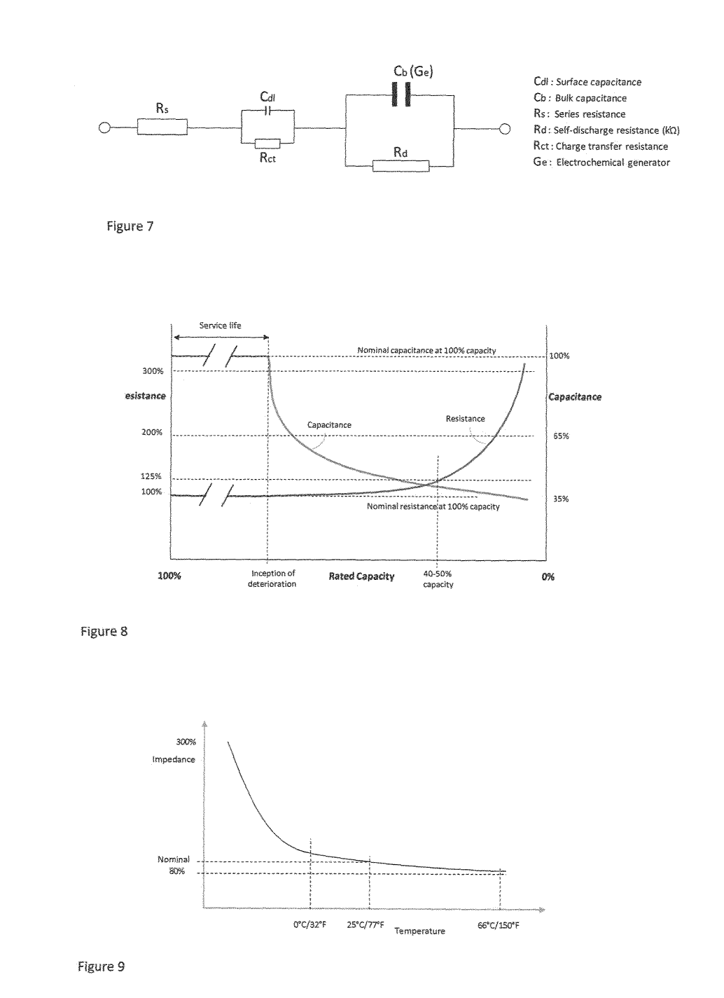

FIG. 7 is a representation of an electrochemical cell by equivalent circuit;

FIG. 8 is a graph of capacitance and resistance behaviour in a deteriorating cell;

FIG. 9 is a graph of the temperature versus impedance for a VRLA cell;

FIG. 10 is a graph of a Gaussian standard deviation curve;

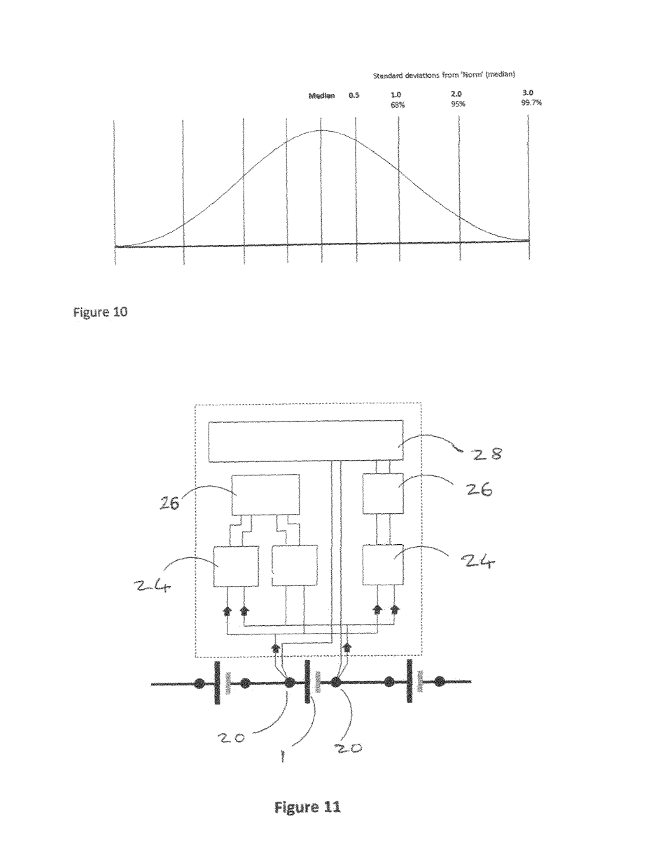

FIG. 11 is a schematic diagram of a first stage of a test according to a third aspect of the invention for measuring cell resistance;

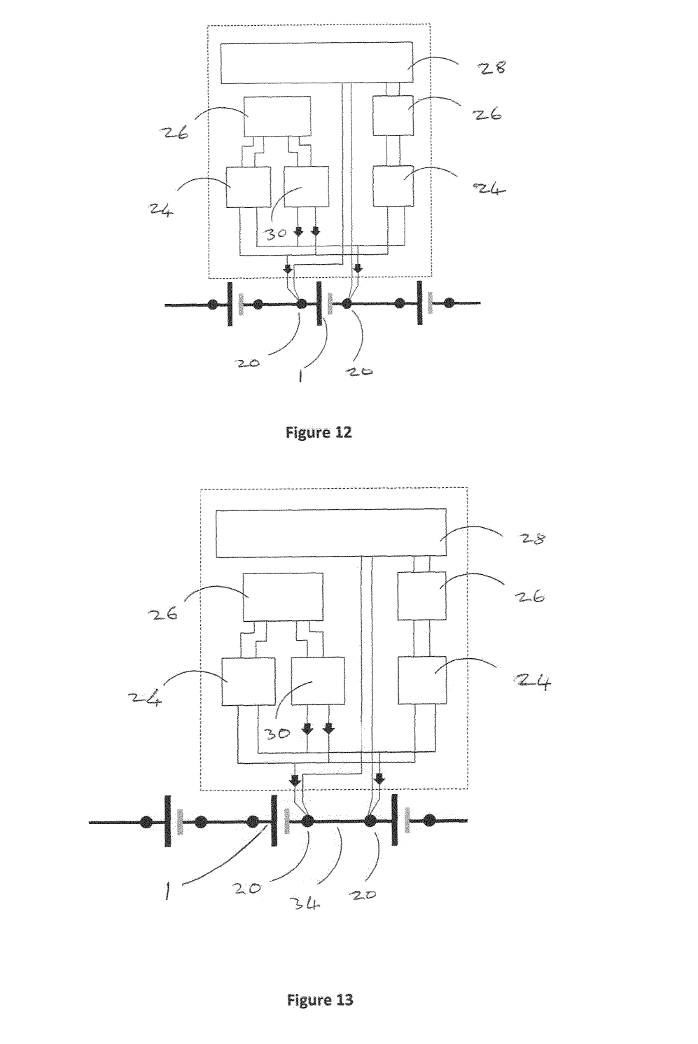

FIG. 12 is a schematic diagram of a second stage of the test of FIG. 10;

FIG. 13 is a schematic diagram of a third stage of the test of FIG. 10;

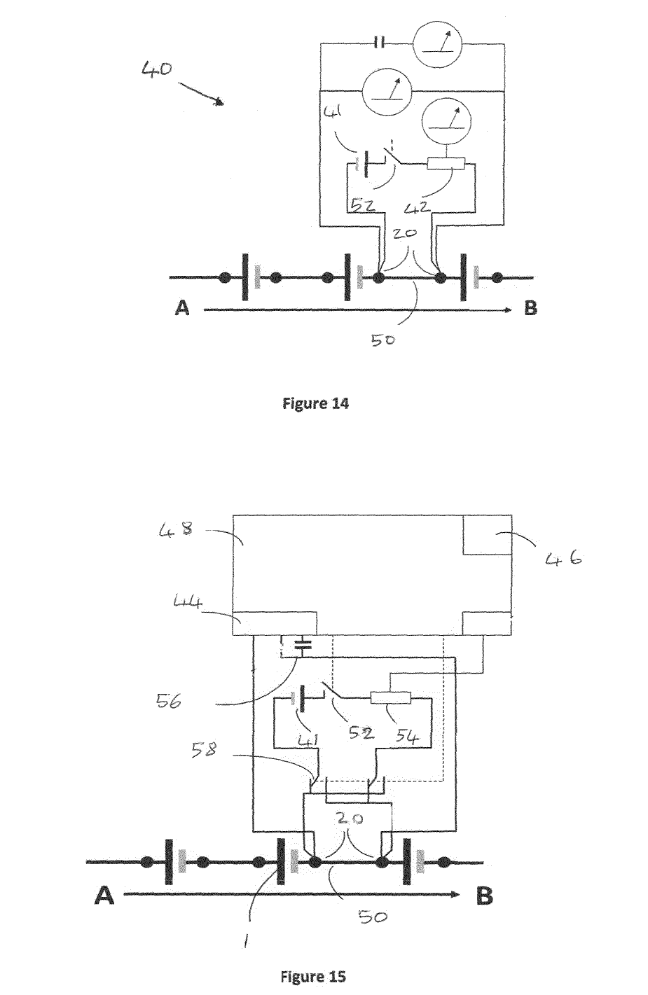

FIG. 14 is a schematic diagram of a test set up according to a fifth aspect of the invention for measuring very low currents; and

FIG. 15 is a schematic diagram of a variation of the test set up of FIG. 14.

### DETERMINING EARLY DETERIORATION IN STANDBY BATTERIES

Standby batteries of the Valve Regulated Lead Acid (VRLA) type are used extensively in the UPS and telecommunications industries. As shown in FIG. 1, the batteries are made up of cells 1 or monoblocs in series or series-parallel connection dependent on the total terminal voltage and/or total current required for the application. A charger 2 and load 3 are also present. The cells 1 are designed to sit on a small float charge all their service lives, to maintain readiness for use in the event of a mains supply failure. Since, in the case of mains failure, in order to prevent equipment failure and severe commercial losses, they must take over support of the critical load in only one or two thousandths of a second, the condition of these cells 1 is crucial.

As VRLA blocs are sealed, it is not possible to obtain the cells' condition, or readiness to support the critical load, other than by disconnecting them from their load systems and discharging them through a large resistive load obtained for the purpose. This is expensive, disruptive and, whilst the most accurate test available, is only effective on the day of testing; one week after a discharge test a battery cannot be said with certainty to be free of faults. Indeed it is not unknown for a high recharge current after a discharge test to activate previously undetected fault conditions in some cells.

In addition, cells of the VRLA, SLA, AGM and GEL types are much more vulnerable to ambient conditions than the traditional free-liquid/pure lead plate Plantè types. For this and other reasons, critical VRLA standby battery systems should be continuously monitored.

A continuous data collection and analysis (continuous monitor) system for standby batteries has the aim of detecting the aging and deterioration of the batteries early enough to take action before the battery has deteriorated enough to prevent it from achieving its specified autonomy (hold-up time). Periodic checks with hand-held instruments are also utilised for this.

Standby batteries are charged by voltage control, that is, the correct voltage for the battery as a whole is fixed by the charger 2, and does not vary. As its terminal voltage is fixed, the individual cell voltage will not change by more than a small amount unless they are in a catastrophic stage of failure, such as shorts or open circuits, which may be too late to prevent failure when they are called upon to support the load 3. Therefore the main advantage of monitoring individual cell DC terminal voltage is to capture individual cell data during a mains-loss discharge, or an autonomy (discharge) test. While measuring terminal voltage under open circuit conditions can indicate problems, it is not possible to detect incipient faults by measuring cell terminal voltage in-line under float conditions.

When a battery is monitored by terminal voltage measurement alone therefore, the first indication of cell problems may only be detected by the battery catastrophically failing to support its critical load during a mains failure.

For the most critical battery systems, the monitored parameters should therefore include the resistance testing of each individual cell 1. Resistance testing is currently the most effective non-intrusive method of determining the on-line condition of a cell 1 and can be carried out by continuous monitoring systems at predetermined periodicity without any significant disturbance to the battery system or its load 3.

Unfortunately, the condition of the cell 1 is imperfectly described by resistance alone. As the condition of the plates and/or the electrolyte deteriorates, the resistance of the cell 1 is well known to rise exponentially, becoming very marked towards the end of life. This exponentiation in resistance can happen gradually over the lifetime of the cell 1, with little or no difference in resistance value taking place in the early stages of failure, but rising sharply towards the end of life, or dramatically and discontinuously when a sudden failure mode develops.

Resistance is therefore not a very reactive indicator in the early stages of deterioration, only changing significantly when the deterioration is well advanced. In addition, several cells 1 in the same battery may have the same internal resistance, yet have widely differing capacities. Therefore, in order to detect the deterioration of a cell 1 early enough to prevent serious failure a further, more sensitive, indicator must be sought.

The standard or ‘norm’ throughout the standby battery industry is that lead-acid batteries are considered to have deteriorated sufficiently to warrant exchanging when the capacity has fallen below 80% of that specified at installation. Unfortunately terminal voltage and resistance alone cannot reliably determine deterioration at this early stage.

Terminal voltage is a very gross indicator of the condition of a cell 1 on float charge, only changing when the cell is in catastrophic failure, and the internal resistance is normally only a reliable indicator when the deterioration is fairly advanced (FIG. 6), therefore a further key parameter must be sought. This tertiary indicator should have the ability to detect incipient failure in a timely manner, before the condition is sufficiently advanced to inhibit the cell's ability to perform as specified.

The invention disclosed herein uses a load connected across the cell 1, to produce a fixed constant current for a short period to perturb the battery under test and measures the battery total voltage response (Vdrop) to derive the cell capacitance. The state of the capacitance of the cell 1 is innovatively utilised as the key indicator of early deterioration in the cell 1 under test.

The required data may be obtained from an in-line cell 1 under float charge conditions by the use of a perturbation device, such as a controlled transistor, drawing a direct current from the cell 1 for a set period, or drawing a pulsed current from the cell 1 with a fixed or variable frequency, also for a set period. The test current may be controlled by an ‘intelligent’ source, or interface device, in this example a microprocessor or Digital Signal Processor (DSP) which measures both the test current drawn and the fall in voltage of the cell 1 engendered by the test current.

A suitable test setup is shown in FIG. 2, and the cell's voltage response to the applied load may be seen in FIGS. 3 and 4.

FIG. 2 shows a cell 1 under test. Two sensing wires 5 are used to record the cell voltage response and two power wires 6 are used to allow perturbation of the cell 1. Also provided are a current limiting measurement shunt 9, a switching device 7 and measurement electronics 4 i.e. DC analogue signal conditioning; electronics for test current control; AC analogue signal conditioning; measurement electronics for DC terminal voltage; measurement electronics for AC current signal and voltage response; processing means and storage memory; and a communications port or similar for the onward transmission of data.

As shown in FIG. 3, there appears to be two vertical components 13 in the graph, one immediately on application of the test current (load) and one immediately after the termination of the test current. However, these components 13 are not truly vertical, but are actually part of the curves which follow. The appearance of verticality is due to the slow timebase of the graph. These vertical components 13 are termed ‘pseudo-vertical’ (Vp) in this document.

In this invention the battery voltage response is assessed in two ways: the overall voltage drop during the period of the test (Vdrop) is measured and evaluated; and the internal resistance is calculated by the standard method of monitoring the pseudo-vertical voltage fall at the initiation of the test and the pseudo-vertical voltage rise at the termination of the test (FIG. 8). The verticality of the two measurements are decided arbitrarily either by limiting the pseudo-vertical fall and rise data to, for example, one millisecond, or calculating the diversion from the vertical by calculating the rate of change of the data and arbitrarily setting a rate-of-change figure at which to terminate the data collection. In both cases the vertical delta V is then divided by the value of the constant current measured during the test, and the two results averaged, to remove the effect of float charge current on the test (it will not affect the results of an open-circuit test).

i.e.: ΔVp(start)/ΔI=R1;ΔVp(termination)/ΔI=R2;(R1+R2)/2=R
Where: ΔVp=pseudo-vertical change in response voltage
ΔI=test current
R=resistance

The invention disclosed herein utilises the overall response voltage drop (Vdrop) engendered by the test current drawn from the cell 1 to predict the early onset of deterioration. Just as the pseudo-vertical fall and rise of response voltage during a constant current test can be an accurate analogue of the cells' internal resistance, the magnitude of the overall voltage response change (Vdrop) is an accurate analogue of the cell capacitance Cdl.

This method may also be used to determine the State of Charge (SoC) and also the State of Health (SoH).

Two examples of a cell's voltage reaction (11, 12) are shown in FIG. 3 to a test current 10, both from the same cell 1, at different stages of deterioration. Also shown are the pseudo-vertical fall and rise 13 of the cell response voltage to a step-change in test current 10.

FIG. 4 is a graph of six tests, carried out on a cell in the early stages of deterioration. The voltage drop, (between points 14 and 15) is of critical significance, and is the basis of this invention.

It can clearly be seen from both FIG. 3 and FIG. 4 that, for each test, the overall depth of voltage response is widely separated, whereas the cell internal resistance, which is directly related to the pseudo-vertical component 13 of the change in voltage response when the test current 10 is instigated or terminated, is identical in magnitude in both (all) cases. In FIG. 4, the response voltage drop is of the greatest magnitude in the test indicated by number 15, and the test with least magnitude drop is indicated by number 16. The six tests were carried out on the same cell 1, where the test indicated by FIG. 4; 15 was before any deterioration, i.e. when the cell still had 100% capacity and the test indicated by FIG. 4; 16 was after removal of 25% of the capacity of the cell 1, in five equal steps of 5% each.

The intervening tests (FIG. 4; between 16 and 17) were each performed after the removal of 5% capacity, and show a progressive reduction of depth of test voltage (Vdrop) as the cell's capacity reduces. The cell's remaining capacity at the end of this series of tests was 75%.

The Vdrop varies little as the deterioration falls from approximately 65% capacity to 45% capacity, at which point (45% capacity) both Vdrop and the internal resistance/impedance begin to increase in magnitude (FIG. 5) in a logarithmic manner.

Two key factors of the tests in FIGS. 3 & 4 are that: the depth of voltage response (Vdrop) is decreasing as the cell's capacity reduces; and the cell's internal resistance does not notably change over the series of six tests, despite a capacity reduction of 25%.

FIG. 5 shows a series of tests during the last 44% of remaining capacity in the same cell 1. Each of the seven tests were carried out between reductions of 8% in the cell's capacity, terminating when the cell 1 was unable to deliver any current and was completely exhausted.

In the ‘end of life’ series of tests disclosed in FIG. 5, both the cell's internal resistance and the depth of cell response voltage (Vdrop) increased as the cell 1 became more exhausted.

The two key factors (depth of test voltage response and internal resistance) can be utilised by the invention. The depth of cell voltage response to any given current stimulus and a depth reducing sequence without a simultaneous change in internal resistance is indicative of the progression of early stage deterioration. Also, the depth of cell voltage response to any given current stimulus and an increasing depth sequence together with a simultaneous change in internal resistance is indicative of the progression of late stage deterioration (FIG. 6).

It is possible to measure the amount (magnitude) of voltage response by various methods, e.g. measuring the start voltage and the voltage immediately before terminating the test current drawn, and subtracting one from the other, or calculating the area of the voltage response, using the start and termination voltage as cardinal points, however the magnitude of the total drop during the test is the key factor.

The invention is applicable to several different platforms and all battery types and chemistries, however the most applicable platforms for standby (stationary) battery systems are the continuous monitoring system, such as the Energy Systems Technology Ltd Watchman™ system and/or a hand-held test instrument.

If sufficient controlled DC current is drawn from an in-line ‘floating’ cell 1 via the switch/resistance network shown in FIG. 2, the cell voltage response behaves in the manner shown in FIG. 3.

There are six easily identifiable components of the cell's voltage response to a constant current load:

1. a pseudo-vertical downward step, when the test load is applied, due in the main to pure resistance

2. a curved portion, due to the first order interaction of cell capacitance and resistance

3. a relatively linear downward sloping section as the cell bulk capacitance (electrochemical generator) begins to react

4. a second, rising, pseudo-vertical, step when the test load is removed and the cell's energy recovers its voltage, again mainly due to resistive reaction.

5. a second curved section due to the resistive-capacitive interaction

6. a second relatively linear section as the bulk capacitance/electrochemical generator recharges the cell voltage, ultimately terminating in the cell's original float voltage value.

Since the first and second pseudo-vertical components are directly related to the DC resistance of the cell parameters, the cell resistance may be simply calculated by Ohms law.

It is well known in electrical theory and practice that the reactions of an electrochemical cell, under stimulus, may be used to identify cell parameters by the employment of a simple equivalent circuit which behaves in the same manner as a cell, when under stimulus. In FIG. 7, a standard Randles equivalent circuit is shown, with the inclusion of the series bulk capacitance (Cb/Ge) in a parallel network with a self-discharge resistance (Rd). The bulk capacitor and discharge resistor are normally not shown in the standard Randles circuit and tend to be ignored when explaining the various electrochemical processes and failure modes of the cell. However, they are significant to the invention and are thus depicted in FIG. 7.

The Metallic Resistance (Rm) represents the resistance of the metal itself, posts, bus bars, grids and plates (paste), and the efficacy of the jointing between them. The Electrolyte Resistance (Re): Electrolyte resistance is affected by the strength of the electrolyte and, to a point, the amount present. The Double Layer Capacitance (Cdl) is derived from parallel conductive plates in the presence of a dielectric medium. Cdl is a function of the effective plate area, and the dielectric strength of the electrolyte, and is mainly due to the double layer of ions immediately adjacent to the plates. The Bulk capacitance (Cb) is representative of the cell's electrochemical generator, which in most test circumstances can be characterised as a capacitor. The Charge Transfer (Faradaic) Resistance (Rct): Is due to limitations in the rates of chemical reaction kinetics at the plate/electrolyte interface. The cell Self-discharge Resistance (Rd) is a fairly high resistance (in the kilohm range) which, in the absence of any charge current will gradually discharge the cell 1.

Referring to FIG. 6; the magnitude of change of test voltage response remains static whilst the cell is at 100% state of health and 100% charged. This is due to the optimum condition of the cell 1; the plates are ‘clean’, thus Rs and Rct are low, Cdl and Cb/Ge are at design maximum and the electrolyte is at optimum strength and capacity.

Cell deterioration in standby lead-acid cells is most commonly due to one of three conditions: negative plate sulphation, often due to undercharge over long periods; positive plate corrosion, often due to overcharge over long periods; or loss of electrolyte, often due to overcharge or elevated temperatures.

All the above three conditions have an early effect and a late effect on the electrical parameters of the cell. In the latter stages of deterioration both the magnitude of Vdrop and the cell resistance increase exponentially, and deviation from par becomes much more pronounced as the condition progresses.

In the early stages of both sulphation and corrosion, the plates begin to lose their ‘pristine’ characteristics, the sulphation and the corrosion begins to form an insulating layer and the initial ion-transport capability of the plates reduces as the plate area starts to reduce. Resistance does not change significantly until the condition has significantly progressed.

However, Cdl, or ‘surface capacitance’ is composed of a double layer of ions at a distance of only a few picometers from the plate surface, and is the smaller of the two capacitances described by several orders of magnitude. Cdl is therefore is much more sensitive to failure modes than Cb and is affected in the early stages of deterioration. Loss of electrolyte (boil-off) similarly reduces the density of the ion layers and the ion-transport capabilities of the plate-electrolyte interface, and Cdl is affected by this. The characteristic of Cdl, as a capacitance, is that it experiences the maximum rate of change at the beginning of its discharge, thus the greatest test voltage delta is when the deterioration of the cell is in the early stages.

Cb is representative of the plate/electrolyte/plate capacitance and the cell's electrochemical generator (Ge), and behaves as much the larger of the two capacitances. Cb is not as sensitive to deterioration and as it is a much more massive energy source than Cdl it does not react as quickly as Cdl to short-term test currents, which are insignificant in comparison to normal load currents. Change in Cb is therefore more notable towards the end of the deterioration process. At this stage the energy available from Cb/Ge is almost exhausted and resistance is becoming a much more significant parameter. It can clearly be seen from FIG. 5 that the resistance related pseudo-vertical fall and rise increase exponentially as the cell becomes exhausted.

Cdl is therefore the key early indicator of the onset of cell deterioration, and the change in Vdrop is a simple, but significant indicator of the state of Cdl and the condition of the cell 1 in the early stages of the cell's deterioration (FIG. 8).

The reduction of Vdrop immediately at the start of loss of capacity is an indicator of the reduction in capacitance of Cdl, whereas the loss of Cb/Ge is characterised by the rise of the magnitude of Vdrop and the detectable increase in resistance/impedance towards the end-of-life of the cell (FIG. 6).

The normal progression of Vdrop in the early stages of cell deterioration is to reduce in magnitude for an increase in deterioration, ceasing further increase at a level determined by the energy of the electrochemical generator/bulk capacitor, while the normal progression of Vdrop and cell resistance in the late stages of cell deterioration is to increase in magnitude as deterioration increases and the plates and/or electrolyte become more corrupted, to the point that the electrochemical reactions cannot take place in any meaningful way.

Therefore, to summarise, the three stages of cell deterioration are:

1. In the early stage of deterioration the more sensitive Cdl begins to deplete and Vdrop becomes smaller; resistance does not change.

2. In the intermediate stage of deterioration the much larger reservoir of Cb/Ge prevents further increases in Vdrop, and little or no any increase in resistance is observed.

3. In the latter stage of deterioration Ge/Cb is nearing exhaustion; as it weakens Vdrop Increases, at the same time the plate/electrolyte/plate condition is rapidly deteriorating (insulating), causing the interplate resistance to increase exponentially.

Cdl is therefore shown to be a better indicator in the early stages of the cell's deterioration than impedance or resistance, since its changes are of greater magnitude as it begins to discharge. It is therefore a more easily detectable and secure parameter at this point as an indicator than resistance in the presence of electrical noise, ripple, etc.

These data (Vdrop & resistance/impedance) may be used in different formats to predict the condition of the battery. An example, using approximate values is given herein, in the form of a simple truth table, as shown in Table 1.

TABLE 1

| | Voltage drop over test | |
|---|---|---|
| | (Vdrop) | Internal resistance |
| Condition | (Progression over time) | (Progression over time) |
| New battery | Increasing | Very slight |
| forming | | decrease/Static |
| 100% SoC, SoH | Static | Static |
| 100% deteriorating | Decreasing | Static/very slight |
| to 65% | | increase |
| 65%%-45% | Static | Slight increase |
| Deterioration greater | Increasing | Increasing exponentially |
| than 50% | | |

The data from the tests may also be utilised in a ‘one-shot’ test by a hand-held instrument, however in such a case it would be useful to have established baselines from discharge testing early in the life of the battery, when it was 100% charged, 100% healthy.

When the invention is employed in a continuous monitor, it is not absolutely essential to establish the baseline reference data, as the movement of the test results may be monitored over time, and the cell condition estimated from this data. However it would certainly be more accurate to establish a baseline State of Health value for Vdrop and a baseline internal resistance, both at 100% fully charged, and again after a discharge (autonomy) test which removes at least 90% of the cell's capacity. These values should be stored and referred to (compared with the current test values) each time the test is performed during the life of the cell 1. The autonomy test must be halted at the 50% capacity level and, after at least 15 minutes at open circuit, a State of Health (Vdrop) test performed, together with tests at 100% and <10%; the 50% level test will allow the State of Health analysis to be accurately compared with established data each time it is performed by the monitoring system.

Once accurately measured, the value for resistance and Vdrop may be juxtaposed in a graphical manner, in a lookup (or truth) table, or used in a sliding scale mathematical algorithm, to provide an insight into the condition of the cell 1. In the case of a graph/lookup table, the axes are based on a percentage of the ‘good’ baseline values derived at the installation of the battery. It must be taken into account that the resistance and capacitance of the cells may change slightly over the first several months of service as the battery ‘forms’ (improves) under float charge.

Since the focus in this invention is for the early detection of deterioration as well as all other stages, the most important values are those of the Vdrop as it begins to reduce in magnitude due to the onset of deterioration. In this early process the cell's internal resistance does not change and this is one of the factors that differentiates the beginning of deterioration from the gross deterioration as the cell 1 nears exhaustion.

Once the weighted results are derived from the graph/lookup table or algorithm and the degree of condition ascertained, the derived data may be employed in two ways.

Firstly, the data can be compared with the same instantaneous data derived from all the other cells in the battery. The complete battery data, when plotted histographically, should approximate a Gaussian distribution (FIG. 10). A computation of the standard deviation of the population, together with appropriate either-side thresholding of (possibly many) staged multiples of the standard deviation (which may be not be integer multiples and would be based on empirical refinement) would allow instantaneous exceptions to be generated, graded for severity. The amount of divergence, and hence the severity, would allow a notification or an alarm to be given respectively. Since the entire battery data will slowly change over its service life, it is important to consider a cell in the context of its peers.

The biased (census) standard deviation, σ, of a group of data x is given by:

$$σ = \frac{\sqrt{n {\sum }_{i = 1}^{n} {x}_{i}^{2} - {( {\sum }_{i = 1}^{n} {x}_{i} )}^{2}}}{{n}^{2}} for n measures of x \qquad ( 1 )$$

The absolute deviation of a single bloc value expressed as a multiple of the standard deviation is given by:

$${α}_{j} = \frac{\vert {v}_{j} - \overline{v} \vert}{σ} for a value v for bloc j \qquad ( 2 )$$

The upper threshold expressed as a theoretical bloc value is

$${v}_{u} = \frac{( u + 100 ) {\sum }_{i = 1}^{n} {v}_{i}}{100 n} for a fractional percentage u above the mean of all blocs n \qquad ( 3 )$$

and the deviation for this bloc expressed as a multiple of the standard deviation is

$${α}_{u} = \frac{\vert {v}_{u} - \overline{v} \vert}{σ} \qquad ( 4 )$$

The lower threshold expressed as a theoretical bloc value is

$${v}_{l} = \frac{( 100 - l ) {\sum }_{i = 1}^{n} {v}_{i}}{100 n} for a fractional percentage l below the mean of all blocs n \qquad ( 5 )$$

and the deviation for this bloc expressed as a multiple of the standard deviation is

$${α}_{l} = \frac{\vert {v}_{l} - \overline{v} \vert}{σ} \qquad ( 6 )$$

Which values α from equations (4) and (6) corresponding to the upper and lower thresholds may be used to discriminate the exception status of samples α (equation 2).

The second way that the derived data may be employed is to compare the instantaneous data with baseline data from the same cell 1 (measured at the installation of the battery), in order to take account of the individual cell's parameters on inception/installation, which may differ from the remainder of the battery. Since not all cells will have the same baseline data, this comparison will show the amount of divergence of the individual cell from its ‘new’ condition. This divergence may also allow a notification or an alarm to be given. The alarm may be set empirically, as a percentage of the baseline data, or as a magnitude, based on the inception values of the cell.

In addition to the above a second, similar, Gaussian distribution set may be used as a gauge of the effectiveness of the battery as a whole, based on the dispersion of the two tables of individual cell results. In this iteration the alarm window may be set empirically, as in the previous iterations.

Since cell electrochemical parameters are known to change with shifts in temperature, the temperature of the cell under test must also be obtained and integrated with the algorithms to qualify the results of the two tables of condition.

Above the temperature at which the battery is rated, normally 25° C./77° F., the resistance and capacitance do not vary a great deal, perhaps up to 15% of the ‘good’ or par value in a few cases, dependant on electrochemical constituents. Below 25° C., however, the resistance begins to increase more sharply, and below 0° C. it rises almost exponentially as the temperature decreases, reaching perhaps 300% of par at very low temperatures. The ability of the cell to deliver its rated current is therefore severely impaired at low temperatures and the resistance values must be adjusted by degree in the algorithm/lookup table to take this into account (FIG. 8).

### Improved Methods and Apparatus for Determining the Resistance of Batteries

The invention also relates to a system for testing the internal resistance of series or series-parallel connected battery system cells and interconnecting straps without the requirement for batteries internal to the testing instrument.

Referring now to FIG. 11, the test apparatus includes Kelvin connections 20, which are well known in the art. These are used to separate the power connections to the cell 1 (through which test current is drawn) from the sense connections (which are measuring the electrical potential difference), thus avoiding any voltage drop across the sense connections when drawing current during testing.

In a first part of the test cycle, energy is drawn in the direction of the arrows 22 from the cell 1 under test by test current energy converters 24 via the power pair of the four-wire Kelvin connections 20.

The energy converter 24, in the direction of the arrows 22, supplies energy to a storage device 26, which in turn supplies stored energy to the control systems 28 to power the operation of the system. The test current energy converters 24 are adapted to accept energy from an ultra-wide range of battery voltage sources and convert this to a suitable level for the energy storage devices 26 to accept.

The energy converter 24 draws a predetermined test current from the cell 1 under test, according to the size of the cell, and this is used to charge the storage device 26, which in this case is used as a test load.

Thus the test current, which charges the energy storage device 26, does not dissipate any energy within the instrument as heat.

The current drawn to charge the load may be measured and used in a calculation of the cell's resistance or impedance or conductance or capacitance, together with the measured response voltage of the cell 1 being tested, sensed by the two sense wires of the Kelvin connection 20 and measured by the control system 28.

Referring now to FIG. 3, when the current and voltage measurement part of the test is complete the majority of the energy presently in the storage device 26 is returned in the direction of arrows 32 to the cell 1 under test at a suitable voltage level by the wide voltage output energy converter 30.

Referring now to FIG. 4, the small amount of energy remaining in the energy storage device 26 is now employed to measure the resistance of the strap 34 connecting the cell 1 to the next cell in series.

The Kelvin connections 20 are connected across the strap 34, from battery cell terminal to the adjacent battery cell terminal. The remaining energy in the energy storage device 26 is now applied as electrical current via the ultra-wide output energy converter 30 to the strap 34.

The applied current and the potential difference or voltage drop between the Kelvin connection sense connections may be measured and recorded, to be used in a calculation by the control electronics 28 to calculate the resistance of the strap 34.

This cycle of tests may be employed for all the battery cells in a series or series parallel arrangement of battery cells. With this invention the battery cell terminal voltage may be measured and recorded as the first step in the cell's test cycle.

Unlike current impedance, resistance or conductance testing technology, the voltage does not rise as the individual tests progress through the series connected cells and therefore it is not required that two separate rounds of testing are made in order to record accurate cell terminal voltages.

The invention provides a resistance test instrument for battery systems which will operate without internal batteries. The instrument can robustly test for individual cell resistance without a significant rise in internal temperature and which causes no significant energy loss to the battery as a whole.

There is no significant increase in heat during the testing process, and the majority of the energy drawn from the cell during the resistance test is returned to the cell during the testing process, thus causing no significant energy loss to the cell under test, and the battery as a whole.

Additionally, the test instrument may be significantly smaller and more maneuverable than current technology, with no risk of burns to the operator or pauses in the testing due to overheating.

### Methods and Apparatus for Measuring Very Low Current

To overcome the problems inherent in the existing methods of very low current measurements in systems where it is difficult or expensive to use traditional methods, this invention proposes means to provide a high accuracy low current measurement, which may be used, not only for the measurement of very low currents, but also for tracing earth leakage problems in battery systems and others.

As shown in FIG. 14, a testing device 40 is attached to accessible connections in the circuit in which the current is to be measured. The device 40 comprises means 41 for the generation of current in the Primary Current Conductor (PCC) 50, means 42 for the measurement of this current and potential difference, and control and evaluation means 44, 46, 48 are. This is done at two positions on a length of passive PCC 50, such as a wire, cable or bus-bar. The PCC 50 may be considered as a short circuit, however the cable itself has a certain resistance, as do any connections included in the circuit section to be measured.

Kelvin connections 20 are used to separate the power connections to the cell 1 (through which test current is drawn) from the sense connections which are measuring the electrical potential difference. This avoids any unwanted voltage drop across the sense connections in the measurement circuit when drawing current during testing.

By means of a switch 52, a single or multiple pulsed or oscillating current is made to flow between the two Kelvin power connections 20 through the PCC 50 by the current generator 41 via the switch 52, which is measured by a shunt resistor 54 in line with the switch 52 and generator 41. The oscillating voltage drop between the two Kelvin sense connections 20 or measuring points is measured via a capacitor 56, which removes the DC float current of the battery system. This value is then divided by the test current, as measured by the shunt 54. A directional switch 58 is maintained in one position during this test.

Since the PCC 50 is a pure resistance, the measurement is unaffected by pulsed current and according to Ohms law (R=V/I) produces a ‘real’ (Ohmic) resistance value for the PCC 50, without any reactive components.

If the DC Potential Difference (PD) between the same measuring points of the PCC 50 is now measured without any application of test current, the measured PD voltage may be divided by the Ohmic resistance calculated from the previous part of the test, again using Ohms law (V/R=I) and the resulting value will be the current in the PCC 50.

A second innovative method may also be employed. Referring to FIG. 15, in this method, by means of the switch 52 and the current generator 41, a single DC pulse of current is applied to the PCC 50 to be measured, via the two Kelvin connections 20.

The direction of the applied current is determined by the second switch 60, in this case in the same direction as the current to be measured (from A to B in FIG. 15). The applied current, as determined by the shunt 54, and the voltage drop between the test connection measuring points, which includes the additive voltage drop caused by the current to be measured, are measured and stored for further calculation.

A further single pulse of test current is then applied to the PCC 50 to be measured, however in this case the direction of test current is reversed by the switch 60 such that its direction is counter to the float current, that is, from B to A.

Now the applied test current, via the shunt 54, and the voltage drop between the test connection measuring points are measured and stored for further calculation. However this voltage drop is now caused by the test current minus the current to be measured.

At this point the two recorded potential differences or volts drops may be added together and the resultant value divided by two, giving a value unaffected by the current flowing in the primary circuit. This voltage may be divided by the test current and the resulting value will be equal to the electrical resistance of the PCC 50. This resistance value may be stored and used in the final calculation.

Now the Potential Differences recorded from both the above tests, one from each test current direction are subtracted, one from the other, the lesser from the greater, and the remainder divided by two. The resulting value is the voltage drop caused by the current to be measured, i.e., that flowing in the primary circuit, may now be divided by the resistance value from the previous calculation.

The result is then the value of the float current flowing in the PCC 50.

If this operation is carried out on every connecting strap, cable or bus-bar in the battery, a current imbalance between the positive and negative terminals of the battery caused by any earth leakage may be detected and the imbalance traced to its causal point, which will be indicated by a change in the system current from one side of the earth leakage point to the other.

The simple design and ease of application of the invention enables very low currents and low current imbalances due to earth leakage to be accurately measured, without the necessity of encircling the conductor in which the current is measured, and without the high cost and problems associated with traditional current transducers.

Various modifications and variations can be made without departing from the scope of the present invention.

1. A method of determining a level of deterioration in a battery, the method comprising:
deriving a value of capacitance for the battery; and
using the derived value of capacitance, deriving the level of deterioration of the battery.

2. A method as claimed in claim 1, including connecting a load to the battery to apply a constant current to the battery and measuring the resulting total voltage drop.

3. A method as claimed in claim 2, including deriving a value of capacitance for the battery from the measured total voltage drop.

4. A method as claimed in any preceding claim, including using a perturbation device to apply the constant current to the battery.

5. A method as claimed in claim 4, wherein the perturbation device comprises a controlled transistor.

6. A method as claimed in any preceding claim, including controlling the current using processing means.

7. A method as claimed in claim 6, wherein the processing means comprises a microprocessor or Digital Signal Processor.

8. A method as claimed in any preceding claim, including determining a resistance value for the battery.

9. A method as claimed in claim 8, including determining a pseudo-vertical voltage drop to determine the resistance value.

10. A method as claimed in claim 9, including determining a first pseudo-vertical voltage change at the start of the test and a second pseudo-vertical voltage change at the end of the test and determining an average pseudo-vertical voltage change from the first pseudo-vertical voltage change and the second pseudo-vertical voltage change.

11. A method as claimed in claim 9 or 10, including using the determined pseudo-vertical voltage change and the determined resistance value together to determine whether the deterioration is at an early or a later stage.

12. A method as claimed in any preceding claim, including deriving a value of the surface capacitance for the battery and, using the derived value of surface capacitance, deriving the level of deterioration of the battery.

13. A method as claimed in any preceding claim, wherein the battery comprises a standby battery comprising a plurality of cells.

14. A method as claimed in claim 13, including deriving a value of capacitance for the cell and, using the derived value of capacitance, deriving the level of deterioration of the cell.

15. A method as claimed in claim 13 or 14, including comparing measured data from one cell with measured data from one or more other cells of the battery.

16. A method as claimed in claim 15, including deriving a Gaussian distribution from the data of all the measured cells.

17. A method as claimed in claim 16, including identifying excessive deterioration of a cell by identifying a standard deviation for a cell which is greater than a predetermined threshold value.

18. A method as claimed in any of claims 13 to 17, including comparing measured data from one cell with historical measured data from the same cell of the battery.

19. A method as claimed in claim 18, including deriving a Gaussian distribution from the measured data and the historical measured data.

20. A method as claimed in any of claims 13 to 19, including measuring the temperature of the cell, and wherein the level of deterioration of the battery is derived using the derived value of capacitance and the temperature of the cell.

21. An apparatus for determining a level of deterioration in a battery, the apparatus comprising:
processing means adapted to:
derive a value of capacitance for the battery; and
using the derived value of capacitance, derive the level of deterioration of the battery.

22. An apparatus as claimed in claim 21, wherein the apparatus includes a load which is connectable to the battery to apply a constant current to the battery, and sensing means for measuring the resulting total voltage drop, and wherein the processing means is adapted to derive a value of capacitance for the battery from the measured total voltage drop.

23. An apparatus as claimed in claim 21 or 22, including a perturbation device to apply the constant current to the battery.

24. An apparatus as claimed in claim 23, wherein the perturbation device comprises a controlled transistor.

25. An apparatus as claimed in any of claims 21 to 24, including a microprocessor or Digital Signal Processor for controlling the current.

26. An apparatus as claimed in any of claims 21 to 24, wherein the processing means is adapted to determine a resistance value for the battery.

27. An apparatus as claimed in claim 26, wherein the processing means is adapted to determine a pseudo-vertical voltage drop to determine the resistance value.

28. An apparatus as claimed in any of claims 21 to 27, wherein the processing means is adapted to derive a value of the surface capacitance for the battery and, using the derived value of surface capacitance, derive the level of deterioration of the battery.

29. An apparatus as claimed in any of claims 21 to 28, wherein the apparatus comprises a mobile or handheld device or a continuous monitoring system.

30. An apparatus as claimed in any of claims 21 to 29, wherein the battery comprises a standby battery.

31. An apparatus as claimed in any of claims 21 to 30, including a temperature sensor for measuring the temperature of the cell, and wherein the processing means is adapted to derive the level of deterioration of the battery using the derived value of capacitance and the temperature of the cell.

32. An apparatus for testing the resistance of a battery comprising:
connection means for connecting the apparatus to the battery;
an energy storage device;
energy conversion means adapted to transfer a first amount of current from the battery to the energy storage device; and
processing means adapted to determine a resistance or capacitance of the battery using the current transferred from the battery,
wherein the energy conversion means is adapted to transfer a second amount of current to the battery from the energy storage device after the resistance or capacitance has been determined.

33. An apparatus as claimed in claim 32, wherein the battery comprises a standby battery comprising a plurality of cells, and wherein the apparatus is adapted to test the resistance of a cell.

34. An apparatus as claimed in claim 32 or 33, wherein the connection means comprises Kelvin connections.

35. An apparatus as claimed in any of claims 32 to 34, wherein the energy storage device is adapted to power the apparatus.

36. An apparatus as claimed in any of claims 32 to 35, wherein the first amount of current is greater than the second amount of current by a third amount of current, and wherein the energy storage device is adapted to store the third amount of current.

37. An apparatus as claimed in any of claims 32 to 36, wherein the apparatus is adapted to measure the resistance of a strap connecting two adjacent cells of the battery.

38. An apparatus as claimed in claim 37, wherein the connection means is connectable to each terminal of the strap.

39. An apparatus as claimed in any of claims 36 to 38, wherein the energy conversion means is adapted to transfer the third amount of current to the strap, and wherein the processing means is adapted to determine the resistance of the strap using the resulting voltage drop from the third amount of current applied to the strap.

40. A method of testing the resistance of a battery comprising:
transferring a first amount of current from the battery to an energy storage device; and
determining the resistance or capacitance of the battery using the current transferred from the battery,
wherein the method includes transferring a second amount of current to the battery from the energy storage device after the resistance or capacitance has been determined.

41. A method as claimed in claim 40, wherein the battery comprises a standby battery comprising a plurality of cells, and wherein the method includes testing the resistance of a cell.

42. A method as claimed in claim 41, including connecting the energy storage device to the cell using Kelvin connections.

43. A method as claimed in any of claims 40 to 42, wherein the first amount of current is greater than the second amount of current by a third amount of current, and wherein the method includes storing the third amount of current in the energy storage device.

44. A method as claimed in any of claims 41 to 43, including measuring the resistance of a strap connecting two adjacent cells of the battery.

45. A method as claimed in claim 44, including transferring the third amount of current to the strap and determining the resistance of the strap using the resulting voltage drop from the third amount of current applied to the strap.

46. A method of measuring a current in a circuit, the method comprising the steps of:
generating a current in a Primary Current Conductor (PCC) of the circuit;
measuring the current flowing between two measuring points along the PCC;
measuring a first voltage drop between the two measuring points;
determining a resistance of the PCC by calculating a ratio of the measured voltage drop and the measured current;
cease generating the current in the PCC;
measuring a second voltage drop between the two measuring points; and
determining the current in the circuit by calculating a ratio of the measured second voltage drop and the determined resistance.

47. A method as claimed in claim 46, wherein the generated current is a single or multiple pulsed or oscillating current.

48. A method as claimed in claim 46 or 47, wherein the generated current is measured using a shunt resistor.

49. A method as claimed in claim 48, wherein the shunt resistor is in series with a current generator.

50. A method as claimed in any of claims 46 to 49, wherein the first voltage drop is measured using a capacitor.

51. A method as claimed in any of claims 46 to 50, including generating the current in the PCC in a first flow direction.

52. A method as claimed in any of claims 46 to 51, wherein the generated current is a single pulse of DC current.

53. A method as claimed in claim 52, including generating a second single pulse of DC current in a second opposite flow direction.

54. A method as claimed in claim 53, including determining the first voltage drop by measuring the voltage drop for each flow direction and determining an average of the measured values.

55. A method as claimed in any of claims 46 to 54, including carrying out the method steps for a plurality of straps of a battery.

56. A method as claimed in any of claims 46 to 55, including detecting any current imbalance between the positive and negative terminals of the total battery caused by any earth leakage.

57. A method as claimed in claim 56, including tracing any current imbalance to its causal location
